(19) United States
(12) Patent Application Publication
(10) Pub. No.: US 2019/0115434 A1
(43) Pub. Date: Apr. 18, 2019

(54) SEMICONDUCTOR DEVICE AND SEMICONDUCTOR WAFER

(71) Applicants: Yazaki Corporation, Tokyo (JP); National University Corporation Hiroshima University, Higashi-Hiroshima City Hiroshima (JP)

(72) Inventors: Naotake SAKUMOTO, Shizuoka (JP); Yoshinori MATSUSHITA, Shizuoka (JP); Hiroki ISHIHARA, Shizuoka (JP); Tatsuo SUNAYAMA, Shizuoka (JP); Misako AIDA, Higashi-Hiroshima-shi (JP); Yoriko TOMINAGA, Higashi-Hiroshima-shi (JP); Dai AKASE, Fukuyama-shi (JP)

(73) Assignees: Yazaki Corporation, Tokyo (JP); National University Corporation Hiroshima University, Higashi-Hiroshima City Hiroshima (JP)

(21) Appl. No.: 16/160,298

(22) Filed: Oct. 15, 2018

(30) Foreign Application Priority Data
Oct. 18, 2017 (JP) 2017-202041

(51) Int. Cl. H01L 29/24; H01L 29/417; H01L 29/78; H01L 29/04

(52) U.S. Cl. CPC H01L 29/24; H01L 29/04; H01L 29/7827; H01L 29/41741

(57) ABSTRACT

Semiconductor devices each include: a semiconductor substrate that contains beta-gallium oxide and has a first conductivity type; a first semiconductor region that contains beta-gallium oxide, has the first conductivity type, and is provided on an upper side of the semiconductor substrate; a second semiconductor region that contains beta-gallium oxide, has a second conductivity type, and is provided on an upper side of a part of the first semiconductor region; and a third semiconductor region that contains beta-gallium oxide, has the first conductivity type, and is provided on an upper side of a part of the second semiconductor region. When the first conductivity type is an n-type and the second conductivity type is a p-type, the second semiconductor region further contains a band gap control element. The band gap control element is selected from a group of boron, aluminum, and indium.

### CROSS-REFERENCE TO RELATED APPLICATION(S)

The present application claims priority to and incorporates by reference the entire contents of Japanese Patent Application No. 2017-202041 filed in Japan on Oct. 18, 2017.

### BACKGROUND OF THE INVENTION

### 1. Field of the Invention

The present invention relates to a semiconductor device and a semiconductor wafer.

### 2. Description of the Related Art

A single crystal substrate of beta-gallium oxide (β-Ga₂O₃), which is one of wide-gap semiconductors, can be manufactured by melt-growth methods in the same manner as silicon. In contrast, techniques for manufacturing single crystal substrates of silicon carbide (SiC) and gallium nitride (GaN), which are other wide-gap semiconductors, by liquid-growth methods are not yet established.

Semiconductor devices using the beta-gallium oxide substrates can be manufactured using facilities for manufacturing silicon substrates. The semiconductor devices using the beta-gallium oxide substrates, thus, can be manufactured more inexpensively than those using the other wide-gap semiconductors. Techniques are disclosed that relate to beta-gallium oxide single crystal substrates on which oxide layers containing Ga such as beta-gallium oxide crystal films can be formed with high quality by efficient epitaxial growth of crystals. Examples of such techniques are disclosed in Japanese Patent Application Laid-open No. 2014-221719.

Beta-gallium oxide has a deep acceptor level. It is, thus, difficult to form a semiconductor region having p-type conductivity at ordinary temperatures even when an impurity element serving as an acceptor is doped into a beta-gallium oxide substrate.

### SUMMARY OF THE INVENTION

The invention aims to provide a semiconductor device and a semiconductor wafer that include a semiconductor region containing beta-gallium oxide and having p-type conductivity at ordinary temperatures.

In order to achieve the above mentioned object, a semiconductor device according to one aspect of the present invention includes a semiconductor substrate that contains beta-gallium oxide and has a first conductivity type; a first semiconductor region that contains beta-gallium oxide, has the first conductivity type, and is provided on an upper side of the semiconductor substrate; a second semiconductor region that contains beta-gallium oxide, has a second conductivity type, and is provided on an upper side of a part of the first semiconductor region; a third semiconductor region that contains beta-gallium oxide, has the first conductivity type, and is provided on an upper side of a part of the second semiconductor region; and a control electrode that faces a portion of the second semiconductor region with an insulating film interposed between the control electrode and the portion, the portion being located between the first semiconductor region and the third semiconductor region, wherein when the first conductivity type is an n-type and the second conductivity type is a p-type, the second semiconductor region further contains a band gap control element, when the first conductivity type is the p-type and the second conductivity type is the n-type, the semiconductor substrate, the first semiconductor region, and the third semiconductor region further contain the band gap control element, and the band gap control element is selected from a group of boron, aluminum, and indium.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a cross-sectional view of a semiconductor device according to a first embodiment;

FIG. 2 is a cross-sectional view of a semiconductor device according to a modification of the first embodiment;

FIG. 3 is a cross-sectional view of a semiconductor wafer according to a second embodiment; and

FIG. 4 is a cross-sectional view of a semiconductor wafer according to a modification of the second embodiment.

### DETAILED DESCRIPTION OF THE PREFERRED EMBODIMENTS

The following describes embodiments of a semiconductor device and a semiconductor wafer according to the invention in detail with reference to the accompanying drawings. The following embodiments do not limit the invention. The constituent components described in the following embodiments include those easily envisaged by those skilled in the art and identical ones.

In the following respective embodiments, a first conductivity type is an n-type while a second conductivity type is a p-type. In the following description, the superscript “+” to n and p such as in n⁺ and p⁺ means that an impurity concentration of the type having the superscript is relatively higher than that of the type having no superscript. Likewise, the superscript “−” to n and p such as in n⁻ and p⁻ means that an impurity concentration of the type having the superscript is relatively lower than that of the type having no superscript.

### First Embodiment

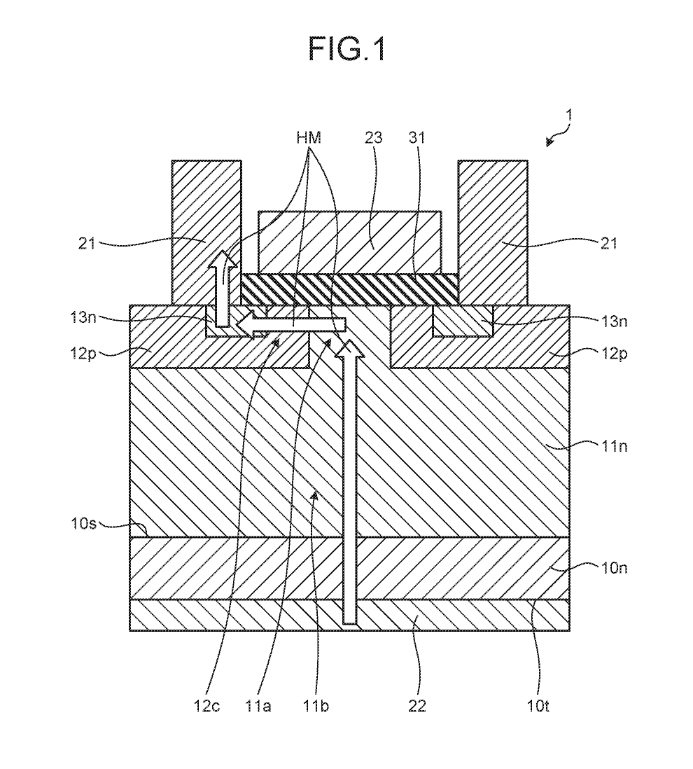

The following describes a first embodiment with reference to FIG. 1. The first embodiment relates to a semiconductor device. FIG. 1 is a cross-sectional view of the semiconductor device according to the first embodiment.

As illustrated in FIG. 1, this semiconductor device 1 according to the first embodiment includes a semiconductor substrate 10n, a first semiconductor region 11n, second semiconductor regions 12p, third semiconductor regions 13n, an insulating film 31, a control electrode 23, a first electrode 21 and a second electrode 22. The semiconductor device 1 according to the first embodiment is a vertical metal oxide semiconductor filed effect transistor (MOSFET) using beta-gallium oxide (β-Ga₂O₃). The semiconductor device 1 according to the first embodiment is what is called a planar MOSFET.

The semiconductor substrate 10n has a first principal surface 10s and a second principal surface 10t. The second principal surface 10t is located on the side opposite to the side where the first principal surface 10s is provided. The semiconductor substrate 10n is a semiconductor substrate that has the first conductivity type (n⁺-type) and contains beta-gallium oxide. In the first embodiment, the semiconductor substrate 10n is a beta-gallium oxide single crystal substrate. The semiconductor substrate 10n is formed using a melt-growth method, for example.

In the first embodiment, the semiconductor substrate 10n contains, as an impurity element serving as a donor, an element selected from a group of silicon (Si), titanium (Ti), zirconium (Zr), hafnium (Hf), vanadium (V), niobium (Nb), tantalum (Ta), molybdenum (Mo), tungsten (W), ruthenium (Ru), rhodium (Rh), yttrium (Ir), carbon (C), tin (Sn), germanium (Ge), palladium (Pd), manganese (Mn), scandium (Sb), bismuth (Bi), iron (Fe), chlorine (Cl), bromine (Br), and iodine (I).

The first semiconductor region 11n is provided on an upper side of the first principal surface 10s of the semiconductor substrate 10n. In the present specification, a side where the first semiconductor region 11n is provided when viewed from the semiconductor substrate 10n is defined as the “upper side” while the side opposite to the side where the first semiconductor region 11n is provided when viewed from the semiconductor substrate 10n is defined as a “lower side”. The upper side and the lower side in the specification may differ from the upper side and the lower side in a practical use.

In the first embodiment, the first semiconductor region 11n is a beta-gallium oxide single crystal film having the first conductivity type (n⁻-type). The first semiconductor region 11n contains, as the impurity element serving as the donor, an element selected from Si, Ti, Zr, Hf, V, Nb, Ta, Mo, W, Ru, Rh, Ir, C, Sn, Ge, Pd, Mn, Sb, Bi, Fe, Cl, Br, and I.

The first semiconductor region 11n includes a first region 11a and a second region 11b. The first region 11a is located on the upper side of a part of the second region 11b. The first region 11a is a junction field effect transistor (JFET) region of the MOSFET. The second region 11b is a drift region of the MOSFET.

The second semiconductor regions 12p are each provided on the upper side of a part of the first semiconductor region 11n. In the first embodiment, the second semiconductor regions 12p are provided on the second region 11b and are in contact with the adjacent first region 11a.

In the first embodiment, the second semiconductor region 12p is a semiconductor region that contains beta-gallium oxide and has p-type conductivity. The second semiconductor region 12p is a p-type well of the MOSFET. The second semiconductor region 12p contains beta-gallium oxide, an impurity element serving as an acceptor, and a band gap control element. The band gap control element can shift the top of a valence band, the energy of which corresponds to a band gap, of the semiconductor containing beta-gallium oxide upward.

In the first embodiment, the second semiconductor region 12p contains, as the impurity element serving as the acceptor, an element selected from a group of beryllium (Be), magnesium (Mg), zinc (Zn), cadmium (Cd), nitrogen (N), phosphorous (P), and arsenic (As). The second semiconductor region 12p contains, as the band gap control element, an element selected from a group of boron (B), aluminum (Al), and indium (In).

In the first embodiment, the first semiconductor region 11n and the second semiconductor regions 12p are formed by the following manner, for example. The beta-gallium oxide single crystal film having the first conductivity type (n⁻-type) is formed on the first principal surface 10s of the semiconductor substrate 10n by epitaxial growth. The band gap control element and the impurity element serving as the acceptor are, then, ion implanted into respective portions each including a part of the top surface of the beta-gallium oxide single crystal film. The portions into which the band gap control element and the impurity element serving as the acceptor are doped by ion implantation of the beta-gallium oxide single crystal film are formed as the second semiconductor regions 12p having the second conductivity type (p-type) while the other portion of the beta-gallium oxide single crystal film is formed as the first semiconductor region 11n. The first semiconductor region 11n and the second semiconductor regions 12p are formed in the manner described above, for example.

The second semiconductor regions 12p may be formed by a thermal diffusion method. In this case, thermal treatment is performed while the band gap control element is in contact with respective parts of the top surface of the beta-gallium oxide single crystal film formed by epitaxial growth on the first principal surface 10s of the semiconductor substrate 10n. As a result of the treatment, the band gap control element is doped into the respective portions of the beta-gallium oxide single crystal film. Thereafter, heat treatment is performed while the impurity element serving as the acceptor is in contact with the respective parts of the top surface of the beta-gallium oxide single crystal film into which the band gap control element has been doped. As a result of the treatment, the second semiconductor regions 12p are formed on the beta-gallium oxide single crystal film. The other portion of the beta-gallium oxide single crystal film is formed as the first semiconductor region 11n. When the second semiconductor regions 12p are formed by the thermal diffusion method, heat treatment may be performed while the impurity element serving as the acceptor is in contact with the respective parts of the top surface of the beta-gallium oxide single crystal film and thereafter heat treatment may be performed while the band gap control element is in contact with the respective parts of the top surface of the beta-gallium oxide single crystal film.

The third semiconductor regions 13n are each provided on the upper side of a part of the second semiconductor region 12p. In the first embodiment, the top surface of the first region 11a, the top surfaces of the second semiconductor regions 12p, and the top surfaces of the third semiconductor regions 13n form a continuous plane. The third semiconductor region 13n is a semiconductor region that contains beta-gallium oxide and has the first conductivity type (n⁺-type). The third semiconductor regions 13n are a source region of the MOSFET. The third semiconductor region 13n contains, as the impurity element serving as the donor, an element selected from Si, Ti, Zr, Hf, V, Nb, Ta, Mo, W, Ru, Rh, Ir, C, Sn, Ge, Pd, Mn, Sb, Bi, Fe, Cl, Br, and I.

The insulating film 31 is provided on the first semiconductor region 11n, the second semiconductor regions 12p, and the third semiconductor regions 13n. The insulating film 31 is continuously provided on the top surface where the first region 11a is exposed of the first semiconductor region 11n, the top surfaces, which continues to the top surface of the first semiconductor region 11n, of the second semiconductor regions 12p and the third semiconductor regions 13n. On the insulating film 31, the control electrode 23 is provided. The control electrode 23 is provided on the upper sides of the first semiconductor region 11n, the second semiconductor regions 12p, and the third semiconductor regions 13n with the insulating film 31 interposed therebetween. The insulating film 31 is a gate insulating film of the MOSFET. The control electrode 23 functions as a gate electrode of the MOSFET.

The first electrode 21 is provided on the second semiconductor regions 12p and the third semiconductor regions 13n. The first electrode 21 is provided such that the first electrode 21 is apart from the control electrode 23. The first electrode 21 is electrically connected to the third semiconductor regions 13n. The first electrode 21 functions as a source electrode of the MOSFET. In the first embodiment, the first electrode 21 is in contact with the top surfaces of the second semiconductor regions 12p and the third semiconductor regions 13n. The first electrode 21 functions as a common electrode of the source region and the p-type wells.

The second electrode 22 is provided on the lower side of the first semiconductor region 11n. The second electrode 22 is electrically connected to the first semiconductor region 11n. The second electrode 22 functions as a drain electrode of the MOSFET. In the first embodiment, the second electrode 22 is provided on the lower side of the first semiconductor region 11n with the semiconductor substrate 10n interposed therebetween. The second electrode 22 is in contact with the second principal surface 10t of the semiconductor substrate 10n.

In the semiconductor device 1 according to the first embodiment, a pair of second semiconductor regions 12p and a pair of third semiconductor regions 13n are provided while the first region 11a is interposed between each of the pairs. The pair of second semiconductor regions 12p include a pair of channel regions 12c. Each channel region 12c is located between the third semiconductor region 13n and the first region 11a.

The control electrode 23 is provided such that the control electrode 23 faces each portion of the second semiconductor region 12p located between the first semiconductor region 11n and the third semiconductor region 13n with the insulating film 31 interposed between itself and the portion. In the first embodiment, the insulating film 31 is provided continuously on the first region 11a, the pair of second semiconductor regions 12p (pair of channel regions 12c) and the pair of third semiconductor regions 13n. The control electrode 23 is provided on the upper side of the pair of the second semiconductor regions 12p and the upper side of the pair of third semiconductor regions 13n with the insulating film 31 interposed therebetween. This structure of the first embodiment allows the single control electrode 23 to control the pair of channels.

In the semiconductor device 1, a voltage is applied between the first electrode 21 and the second electrode 22 in such a manner that potential of the second electrode 22 is negative relative to the first electrode 21. At this time, electrical conduction between the first electrode 21 and the second electrode 22 is controlled by the control electrode 23. When a positive voltage equal to or larger than a threshold voltage is applied to the control electrode 23, an inversion layer is formed in each of the channel regions 12c located on the lower side of the control electrode 23. The inversion layer formed in the channel region 12c allows the first semiconductor region 11n and the third semiconductor region 13n to be electrically connected. The first semiconductor region 11n and the third semiconductor region 13n are electrically connected in this way. As a result, a current flows from the second electrode 22 (drain electrode) to the first electrode 21 (source electrode) as illustrated with arrow HM in FIG. 1. The semiconductor device 1, thus, becomes an on state.

In contrast, when a positive voltage equal to or larger than the threshold voltage is not applied to the control electrode 23, no inversion layer is formed in each of the channel regions 12c. An inversely biased state is maintained between the first semiconductor region 11n and the second semiconductor region 12p. The semiconductor device 1, thus, becomes an off state. The semiconductor device 1 according to the first embodiment is a normally-off type MOSFET.

### Test Example

The following describes how to form a semiconductor region containing beta-gallium oxide and having the p-type conductivity with reference to a test example. Table 1 illustrates band gaps of beta-gallium oxide and beta-gallium oxide in which boron atoms are substituted for some of gallium atoms. The band gaps were calculated by simulation calculation. The band gaps illustrated in Table 1 were calculated as follows: a crystal structure of beta-gallium oxide was made by applying a three-dimensional periodic boundary conditions to a unit cell of beta-gallium oxide, and the band gaps were calculated on the basis of quantum mechanical calculation using a density-functional approach.

TABLE 1

| Structure | Ga₂O₃ | (Ga₍₁₋ₓ₎Bₓ)₂O₃ |
|---|---|---|
| Band gap (eV) | 2.61 | 2.00 |

As illustrated in Table 1, the band gap of beta-gallium oxide in which boron atoms are substituted for some of gallium atoms is smaller than that of beta-gallium oxide without atom substitution.

Table 2 illustrates acceptor levels when respective elements each capable of serving as the acceptor are doped in beta-gallium oxide. The acceptor levels were calculated by simulation calculation. The acceptor levels illustrated in table 2 were calculated as follows: a crystal structure of beta-gallium oxide was made by applying a three-dimensional periodic boundary conditions to a unit cell of beta-gallium oxide, and the acceptor levels when respective elements each serving as the acceptor are doped were calculated on the basis of quantum mechanical calculation using a density-functional approach.

TABLE 2

| | Impurity element | | | | | |
|---|---|---|---|---|---|---|
| | Be | Mg | Zn | N | P | As |
| Acceptor level (eV) | 0.14 | 0.22 | 0.32 | 1.02 | 0.17 | 0.23 |

As the results illustrated in Table 2, the acceptor levels were formed by doping the impurity elements (Be, Mg, Zn, Cd, N, P, and As) each capable of serving as the acceptor into beta-gallium oxide. The calculated values of acceptor levels formed by Be, Mg, P, and As were smaller than those of acceptor levels formed by Zn and N.

Semiconductors having an acceptor level equal to or smaller than 80 meV become p-type semiconductors at ordinary temperatures. As illustrated in Table 2, the acceptor level equal to or smaller than 100 meV was not formed by doping only each impurity element capable of serving as the acceptor into beta-gallium oxide. It is, thus, difficult to form a semiconductor region having the p-type conductivity at ordinary temperatures by doping only the impurity element capable of serving as the acceptor into the beta-gallium oxide single crystal film.

As illustrated in Table 1, the formed band gap is reduced when the band gap control element is doped into beta-gallium oxide. The top of the valence band, the energy of which corresponds to the band gap, is shifted upward from the valence band when the band gap control element is not doped. In addition to the upward shift of the top of the valence band, the bottom of a conduction band is shifted downward from the conduction band when the band gap control element is not doped.

In addition to doping of the impurity element serving as the acceptor, the band gap control element is doped into beta-gallium oxide. As a result, the acceptor level is changed with a change in band gap. The doping of the impurity element serving as the acceptor and the band gap control element into beta-gallium oxide makes it possible to form a shallower acceptor level than that formed when only the impurity element serving as the acceptor is doped into beta-gallium oxide.

The band gap of beta-gallium oxide can be controlled by a concentration of the band gap control element in substitution. The band gap of beta-gallium oxide is larger than those of silicon carbide (SiC) and gallium nitride (GaN), which are other wide gap semiconductors. For example, a value of the band gap of a semiconductor region can be controlled in a range from the band gap value of silicon to the band gap value of beta-gallium oxide by doping the band gap control element into the semiconductor region containing beta-gallium oxide. In addition, by doping the band gap control element and the impurity element serving as the acceptor into a semiconductor region containing beta-gallium oxide, the semiconductor region having the p-type conductivity at ordinary temperatures is formed while characteristics of a wide band gap semiconductor are maintained in beta-gallium oxide.

### Modification of First Embodiment

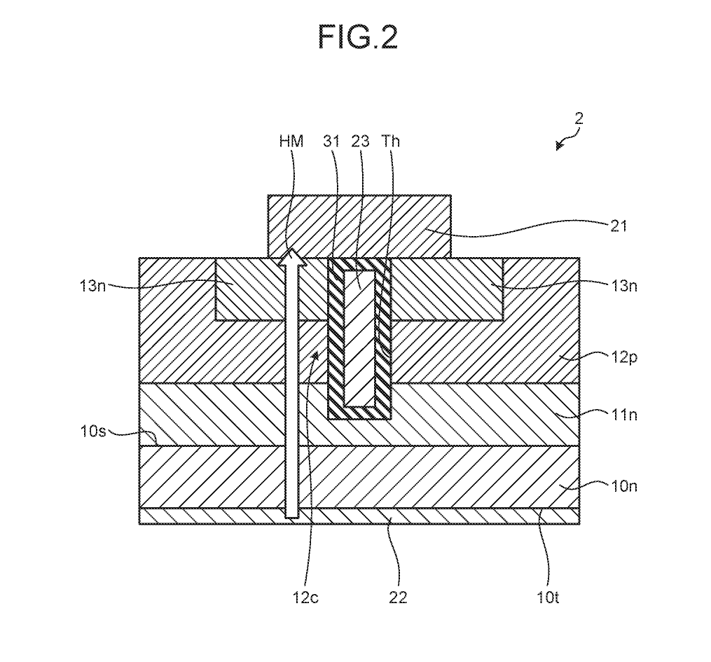

The following describes a modification of the first embodiment. The modification relates to a semiconductor device. FIG. 2 is a cross-sectional view of the semiconductor device according to the modification of the first embodiment. This semiconductor device 2 according to the modification is a vertical MOSFET using beta-gallium oxide. The semiconductor device 2 in the modification is what is called a trench structure MOSFET.

The modification differs from the first embodiment in that the control electrode 23 is provided in a trench Th with the insulating film 31 surrounding the control electrode 23. The trench Th is provided from the top surface of the third semiconductor region 13n to the upper portion of the first semiconductor region 11n.

As illustrated in FIG. 2, in the semiconductor device 2 according to the modification, a pair of second semiconductor regions 12p and a pair of third semiconductor regions 13n are provided while the control electrode 23 is interposed between each of the pairs. The first electrode 21 is continuously provided on the pair of third semiconductor regions 13n and on the upper side of the control electrode 23. The insulating film 31 is also provided between the first electrode 21 and the control electrode 23. The first electrode 21 and the control electrode 23 are, thus, insulated from each other.

In the modification, the semiconductor substrate 10n is the first conductivity type (n⁺-type). The first semiconductor region 11n provided on the upper side of the semiconductor substrate 10n is the first conductivity type (n⁻-type). The second semiconductor regions 12p each provided on the upper side of a part of the first semiconductor region 11n have the second conductivity type (p-type). The conductivity type of the third semiconductor regions 13n each provided on the upper side of a part of the second semiconductor region 12p is the first conductivity type (n⁺-type).

In the modification, the channel regions 12c are formed, as a pair, in respective regions in the second semiconductor regions 12p located on both sides of the control electrode 23. The channel region 12c is located between the first semiconductor region 11n and the third semiconductor region 13n in the direction from the lower side to the upper side.

The semiconductor substrate 10n, the first semiconductor region 11n, and the third semiconductor regions 13n contain beta-gallium oxide and the impurity element serving as the donor. The semiconductor substrate 10n, the first semiconductor region 11n, and the third semiconductor regions 13n contain, as the impurity element serving as the donor, an element selected from Si, Ti, Zr, Hf, V, Nb, Ta, Mo, W, Ru, Rh, Ir, C, Sn, Ge, Pd, Mn, Sb, Bi, Fe, Cl, Br, and I.

The semiconductor substrate 10n, the first semiconductor region 11n, and the third semiconductor regions 13n may contain the band gap control element in addition to the impurity element serving as the donor. The semiconductor substrate 10n, the first semiconductor region 11n, and the third semiconductor regions 13n may include, as the band gap control element, an element selected from a group of B, Al, and In.

The second semiconductor region 12p contains beta-gallium oxide, the impurity element serving as the acceptor, and the band gap control element. The second semiconductor region 12p contains, as the impurity element serving as the acceptor, an element selected from a group of Be, Mg, Zn, Cd, N, P, and As. The second semiconductor region 12p contains, as the band gap control element, an element selected from a group of B, Al, and In.

In the semiconductor device 2, the electrical conduction between the first electrode 21 and the second electrodes 22 is controlled by the control electrode 23. As illustrated with arrow HM in FIG. 2, a current flows from the second electrode 22 (drain electrode) to the first electrode 21 (source electrode). When a positive voltage equal to or larger than a threshold voltage is applied to the control electrode 23, the inversion layer is formed in each of the channel regions 12c located on both sides of the control electrode 23. The inversion layer formed in each channel region 12c results in the semiconductor device 2 becoming an on state.

In contrast, when a positive voltage equal to or larger than the threshold voltage is not applied to the control electrode 23, no inversion layer is formed in each of the channel regions 12c. The semiconductor device 2, thus, becomes an off state. The semiconductor device 2 according to the modification of first embodiment is a normally-off type MOSFET.

In the first embodiment, the second semiconductor regions 12p and the third semiconductor regions 13n are formed by the ion implantation method or the thermal diffusion method. The second semiconductor regions 12p and the third semiconductor regions 13n each may be the beta-gallium oxide single crystal film. In this case, the second semiconductor region 12p can be formed by doping the impurity element serving as the acceptor and the band gap control element concurrently with epitaxial growth using molecular beam epitaxy (MBE). The third semiconductor region 13n can be formed by doping the impurity element serving as the donor concurrently with epitaxial growth using MBE.

In the first embodiment and the modification of the first embodiment, the first conductivity type is the n-type while the second conductivity type is the p-type. The first embodiment and the modification of the first embodiment can employ the p-type as the first conductivity type and the n-type as the second conductivity type. The second semiconductor regions 12p may contain the impurity element serving as the donor. The semiconductor substrate 10n, the first semiconductor region 11n, and the third semiconductor regions 13n may contain the impurity element serving as the acceptor and the band gap control element.

When the first conductivity type is the n-type and the second conductivity type is p-type, the second semiconductor regions 12p contain the impurity element serving as the acceptor and the band gap control element. When the first conductivity type is the p-type and the second conductivity type is n-type, the semiconductor substrate 10n, the first semiconductor region 11n, and the third semiconductor regions 13n contain the impurity element serving as the acceptor and the band gap control element. The band gap control element may be contained in each of the semiconductor substrate 10n, the first semiconductor region 11n, the second semiconductor regions 12p, and the third semiconductor regions 13n. When the second semiconductor region 12p is the p-type, at least one of the semiconductor substrate 10n, the first semiconductor region 11n, and the third semiconductor regions 13p that have the n-type conductivity may contain the band gap control element.

As described above, the semiconductor device 1 according to the first embodiment and the semiconductor device 2 according to the modification of the first embodiment each include the semiconductor substrate 10n having the first conductivity type, the first semiconductor region 11n having the first conductivity type, the second semiconductor regions 12p having the second conductivity type, the third semiconductor regions 13n having the first conductivity type, and the control electrode 23. The semiconductor substrate 10n contains beta-gallium oxide. The first semiconductor region 11n contains beta-gallium oxide and is provided on the upper side of the semiconductor substrate 10n. The second semiconductor regions 12p contain beta-gallium oxide and are each provided on the upper side of a part of the first semiconductor region 11n. The third semiconductor regions 13n contain beta-gallium oxide and are each provided on the upper side of a part of the second semiconductor region 12p. The control electrode 23 faces each portion of the second semiconductor region 12p located between the first semiconductor region 11n and the third semiconductor region 13n with the insulating film 31 interposed between itself and the portion. When the first conductivity type is the n-type and the second conductivity type is the p-type, the second semiconductor regions 12p further contain the band gap control element. When the first conductivity type is the p-type and the second conductivity type is the n-type, the semiconductor substrate 10n, the first semiconductor region 11n, and the third semiconductor regions 13n further contain the band gap control element. The band gap control element is selected from a group of boron, aluminum, and indium.

The semiconductor device 1 according to the first embodiment and the semiconductor device 2 according to the modification of the first embodiment each include the semiconductor substrate 10n containing beta-gallium oxide, the semiconductor regions (the first semiconductor region 11n and the third semiconductor regions 13n) containing beta-gallium oxide and having the n-type conductivity, and the semiconductor regions (the second semiconductor regions 12p) containing beta-gallium oxide and having the p-type conductivity type. The semiconductor substrate 10n included in each of the semiconductor device 1 according to the first embodiment and the semiconductor device 2 according to the modification of the first embodiment can be manufactured by the melt-growth method, thereby making it possible to use facilities for manufacturing silicon substrates. The use of the facilities for manufacturing silicon substrates allows the semiconductor device using beta-gallium oxide that is the wide gap semiconductor to be manufactured inexpensively.

The single crystal substrates of silicon carbide and gallium nitride are manufactured by mainly a vapor-phase growth method. The techniques for manufacturing the single crystal substrates of silicon carbide and gallium nitride using the melt-growth method are not yet established. In contrast, the semiconductor substrate 10n in the first embodiment can be formed as the single crystal substrate using the melt-growth method. The melt-growth method allows the single crystal substrate having a large diameter to be manufactured with a lower cost and lower power consumption than the vapor-phase growth method. The first embodiment, thus, can manufacture the semiconductor device using the wide gap semiconductor more inexpensively than a case where the other wide gap semiconductors such as silicon carbide and gallium nitride are used.

The first embodiment can provide the semiconductor region having the p-type conductivity at ordinary temperatures in the semiconductor device using beta-gallium oxide by using the band gap control element. The semiconductor device according to the first embodiment allows the formation of a homo junction between the n-type semiconductor region and the p-type semiconductor region, for example. The homo junction between the n-type semiconductor region and the p-type semiconductor region can increase a breakdown voltage of the semiconductor device because of its crystal structure. The normally-off MOSFET using beta-gallium oxide can be achieved by the semiconductor device provided with the semiconductor region containing beta-gallium oxide and having the p-type conductivity at ordinary temperatures, for example.

The band gap of the semiconductor region can be controlled by the band gap control element. The semiconductor device 1 according to the first embodiment and the semiconductor device 2 according to the modification of the first embodiment allow any band gaps to be formed as the band gaps of the semiconductor region and the semiconductor substrate. The band gap control element can control the characteristics (characteristics due to the band gap such as a switching characteristic and a breakdown voltage characteristic) of the semiconductor device.

In the semiconductor device 1 according to the first embodiment and the semiconductor device 2 according to the modification of the first embodiment, when the first conductivity type is n-type and the second conductivity type is p-type, at least one of the semiconductor substrate 10n, the first semiconductor region 11n, and the third semiconductor regions 13n may further contain the band gap control element. When the first conductivity type is p-type and the second conductivity type is n-type, the second semiconductor regions 12p may further contain the band gap control element.

In the semiconductor device 1 according to the first embodiment and the semiconductor device 2 according to the modification of the first embodiment, at least one of the semiconductor substrate 10n, the first semiconductor region 11n, the second semiconductor regions 12p, and the third semiconductor regions 13n contains the band gap control element. When the band gap control element is used for the semiconductor region having the n-type conductivity, the conductivity in the n-type semiconductor region can be easily controlled by the band gap control element.

### Second Embodiment

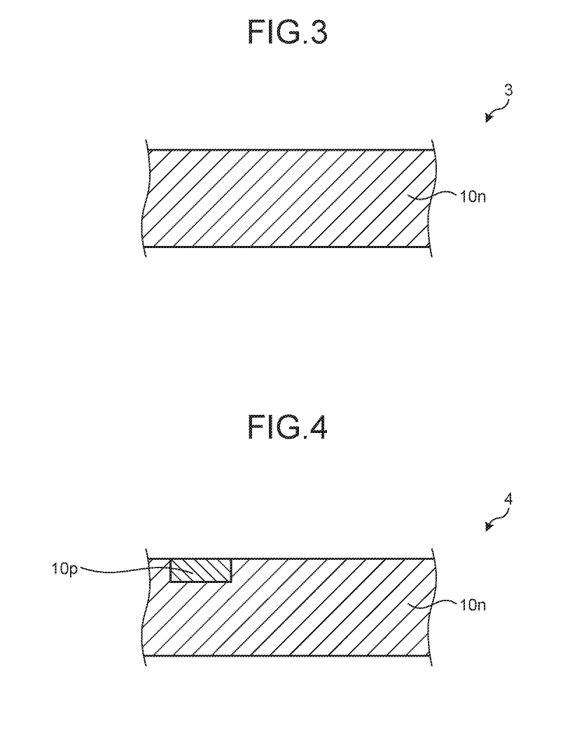

The following describes a second embodiment with reference to FIG. 3. The second embodiment relates to a semiconductor wafer. FIG. 3 is a cross-sectional view of the semiconductor wafer according to the second embodiment.

As illustrated in FIG. 3, this semiconductor wafer 3 according to the second embodiment includes the semiconductor substrate 10n containing beta-gallium oxide. In the third embodiment, the semiconductor substrate 10n is the beta-gallium oxide single crystal substrate having the p-type conductivity. The semiconductor substrate 10n contains beta-gallium oxide, the impurity element serving as the acceptor, and the band gap control element.

The semiconductor substrate 10n contains, as the impurity element serving as the acceptor, an element selected from a group of Be, Mg, Zn, Cd, N, P, and As. The semiconductor substrate 10n contains, as the band gap control element, an element selected from a group of B, Al, and In.

The semiconductor substrate 10n is formed using the melt-growth method, for example. In this case, the semiconductor substrate 10n is formed using melt of beta-gallium oxide mixed with the band gap control element and the impurity element serving as the acceptor. The semiconductor substrate 10n has the p-type conductivity at ordinary temperatures.

### Modification of Second Embodiment

The following describes a modification of the second embodiment. The modification relates to a semiconductor wafer. FIG. 4 is a cross-sectional view of the semiconductor wafer according to the modification of the second embodiment. This semiconductor wafer 4 according to the modification includes the semiconductor substrate 10n and a semiconductor region 10p. In the modification, the semiconductor substrate 10n is the beta-gallium oxide single crystal substrate. In the modification, the semiconductor substrate 10n has the n-type conductivity.

On a part of the semiconductor substrate 10n, the semiconductor region 10p is provided. The semiconductor region 10p has the p-type conductivity at ordinary temperatures. The semiconductor region 10p contains beta-gallium oxide, the impurity element serving as the acceptor, and the band gap control element.

The semiconductor region 10p contains, as the impurity element serving as the acceptor, an element selected from a group of Be, Mg, Zn, Cd, N, P, and As. The semiconductor region 10p contains, as the band gap control element, an element selected from a group of B, Al, and In. The semiconductor region 10p can be formed by the ion implantation method or the thermal diffusion method.

The semiconductor region 10p may be a film formed on the semiconductor substrate 10n by epitaxial growth. In this case, the semiconductor region 10p is a p-type semiconductor film provided on the principal surface of the semiconductor substrate 10n. The semiconductor region 10p can be formed by doping the impurity element serving as the acceptor and the band gap control element concurrently with the forming of the beta-gallium oxide single crystal film by epitaxial growth using MBE. The semiconductor region 10p may be provided above the semiconductor substrate 10n with another film provided on the semiconductor substrate 10n interposed therebetween.

As described above, the semiconductor wafer 3 according to the second embodiment and the semiconductor wafer 4 according to the modification of the second embodiment each include the semiconductor region (e.g., semiconductor region 10p) having the p-type conductivity. The semiconductor region contains beta-gallium oxide and the band gap control element. The band gap control element is an element selected from a group of boron, aluminum, and indium.

In the second embodiment, the semiconductor region having the p-type conductivity may be the semiconductor substrate 10n containing beta-gallium oxide.

In the second embodiment, the semiconductor region having the p-type conductivity may be the semiconductor region 10p provided on the semiconductor substrate 10n containing beta-gallium oxide.

The semiconductor wafer 3 according to the second embodiment and the semiconductor wafer 4 according to the modification of the second embodiment each include the semiconductor region that contains beta-gallium oxide and the band gap control element and has the p-type conductivity. In the second embodiment, the semiconductor region having the p-type conductivity can be provided on the semiconductor wafer using beta-gallium oxide by using the band gap control element. The normally-off MOSFET using beta-gallium oxide described in the first embodiment can be achieved using the semiconductor wafer 4 according to the modification of the second embodiment, for example.

The band gap of the semiconductor region can be controlled by a concentration of the band gap control element. The semiconductor wafers 3 and 4 each including the semiconductor region having a desired band gap in a range equal to or smaller than the band gap of beta-gallium oxide can be used for various semiconductor devices, for example. For example, the semiconductor wafer 3 can be used for a substrate of a semiconductor device such as the MOSFET.

Contents disclosed in the respective embodiments and modifications can be implemented by combining them appropriately.

In the semiconductor device according to the embodiments, the semiconductor substrate, the first semiconductor region and the third semiconductor regions, or the second semiconductor regions contain the band gap control element. The band gap control element reduces the band gaps of the semiconductor substrate and the semiconductor regions, thereby making it possible to achieve the shallow acceptor levels. The invention has an advantageous effect of being capable of providing the semiconductor region having the p-type conductivity at ordinary temperatures in the semiconductor device using beta-gallium oxide by achieving the shallow acceptor level of the semiconductor region containing beta-gallium oxide.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor device comprising:
a semiconductor substrate that contains beta-gallium oxide and has a first conductivity type;
a first semiconductor region that contains beta-gallium oxide, has the first conductivity type, and is provided on an upper side of the semiconductor substrate;
a second semiconductor region that contains beta-gallium oxide, has a second conductivity type, and is provided on an upper side of a part of the first semiconductor region;
a third semiconductor region that contains beta-gallium oxide, has the first conductivity type, and is provided on an upper side of a part of the second semiconductor region; and
a control electrode that faces a portion of the second semiconductor region with an insulating film interposed between the control electrode and the portion, the portion being located between the first semiconductor region and the third semiconductor region, wherein
when the first conductivity type is an n-type and the second conductivity type is a p-type, the second semiconductor region further contains a band gap control element,
when the first conductivity type is the p-type and the second conductivity type is the n-type, the semiconductor substrate, the first semiconductor region, and the third semiconductor region further contain the band gap control element, and
the band gap control element is selected from a group of boron, aluminum, and indium.

2. The semiconductor device according to claim 1, wherein
when the first conductivity type is the n-type and the second conductivity type is the p-type, at least one of the semiconductor substrate, the first semiconductor region, and the third semiconductor region further contains the band gap control element, and
when the first conductivity type is the p-type and the second conductivity type is the n-type, the second semiconductor region further contains the band gap control element.

3. A semiconductor wafer comprising:
a semiconductor region having p-type conductivity, wherein
the semiconductor region contains beta-gallium oxide, an impurity element serving as an acceptor, and a band gap control element, and
the band gap control element is selected from a group of boron, aluminum, and indium.

4. The semiconductor wafer according to claim 3, wherein
the semiconductor region is a semiconductor substrate.

5. The semiconductor wafer according to claim 3, further comprising:
a semiconductor substrate containing beta-gallium oxide, wherein
the semiconductor region is provided on the semiconductor substrate.
